(19) United States
(12) Patent Application Publication
(10) Pub. No.: US 2026/0012220 A1
(43) Pub. Date: Jan. 8, 2026

(54) Off-Chip Interface

(71) Applicant: FOREFRONT RF LTD, Cambridge (GB)

(72) Inventors: Leo Laughlin, Cambridge (GB); Julian Hildersley, Cambridge (GB)

(21) Appl. No.: 19/126,357

(22) PCT Filed: Oct. 31, 2023
(86) PCT No.: PCT/GB2023/052834

§ 371 Date: May 1, 2025

(30) Foreign Application Priority Data
Nov. 4, 2022 (GB) 2216466.9

(51) Int. Cl. H04B 1/525; H03H 7/46

(52) U.S. Cl. CPC H04B 1/525; H03H 7/461

(57) ABSTRACT

A transceiver circuit implemented on one or more integrated circuits, the transceiver comprising: a signal transmitter for forming a radio signal for transmission; a signal receiver for performing receive processing on a received radio signal; and a cancellation circuit for at least partially cancelling components of the signal for transmission in the signal receiver, the cancellation circuit being arranged to receive an input from the signal transmitter and to provide a cancellation output to the signal receiver, the cancellation circuit being configured to form the cancellation output in dependence on both the input from the signal transmitter and a response received from a first external connection pad of one of the integrated circuits.

This invention relates to integrated circuits having interfaces to external components.

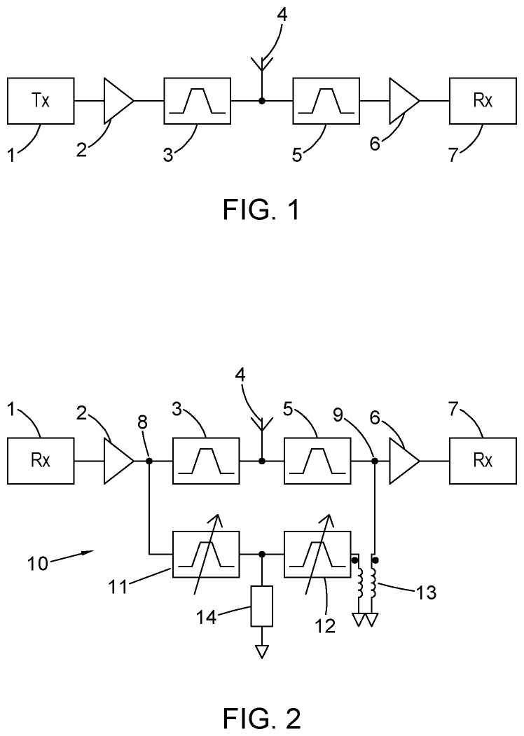

FIG. 1 shows the general architecture of a radio transceiver of a type that is typical in portable devices such as mobile phones. A transmission section 1 generates a signal for transmission. The signal for transmission is amplified by amplifier 2, bandpass filtered by transmission filter 3 and fed to antenna 4 for transmission. Signals received by the antenna 4 are bandpass filtered by receive filter 5, amplified by amplifier 6 and then processed by receive section 7. The transmit and receive filters are both connected to the antenna 4. Therefore, it is possible for the transmit signal from filter 3 to reach the input of filter 5. If the transmit and receive frequency bands do not overlap then in principle it might be possible for filters 3 and 5 to cooperate so that the transmit signal is fully suppressed from reaching the receive section 7. However, this is hard to achieve in practice without using large or expensive filters.

FIG. 2 shows an alternative arrangement. Like components are numbered as in FIG. 1. A cancellation path 10 is coupled between the input 8 to the transmit filter 3 and the output 9 of the receive filter 5. The aim of the cancellation path is to generate a signal at 9 that cancels any element of the transmit signal that may have been passed by receive filter 5. A cancellation path of this type may be configured in different ways. In the example of FIG. 2, it comprises tuneable filters 11 and 12, a transformer 13 and a balancing impedance 14. The filters 11, 12 are tuned with the aim of generating the desired cancellation signal at 9. The balancing impedance is intended to balance the impedance of the antenna. In practical circuits it can be difficult to properly balance the impedance of the antenna, especially when the cancellation path is implemented on an integrated circuit.

There is a need for an improved form of transceiver and/or cancellation circuit.

According to one aspect there is provided a transceiver circuit implemented on one or more integrated circuits, the transceiver circuit comprising: a signal transmitter for forming a radio signal for transmission; a signal receiver for performing receive processing on a received radio signal; and a cancellation circuit for at least partially cancelling components of the signal for transmission in the signal receiver, the cancellation circuit being arranged to receive an input from the signal transmitter and to provide a cancellation output to the signal receiver, the cancellation circuit being configured to form the cancellation output in dependence on both the input from the signal transmitter and a response received from a first external connection pad of the or one of the integrated circuit(s).

The said response may be a reactive response to a signal formed by the cancellation circuit in dependence on the input from the signal transmitter.

The cancellation circuit may comprise a first filter coupled between the signal transmitter and the external connection pad and a second filter coupled between the external connection pad and the signal receiver. The first filter may be fixed or adjustable. The second filter may be fixed or adjustable. The filters may be interconnected on the or one of the integrated circuits. Thus the cancellation circuit may be embodied in an operational form on the integrated circuit(s). The filters may be coupled to connection pads whereby they can be interconnected to a link between the pads that is external to the integrated circuit(s). In such an embodiment the filters might not be interconnected on the or one of the integrated circuits. Thus the cancellation circuit might not be embodied in an operational form on the integrated circuit(s).

The cancellation circuit may comprise a first adjustable filter coupled between the signal transmitter and the external connection pad and a second adjustable filter coupled between a further external connection pad and the signal receiver, whereby the first and second adjustable filters may be interconnected by an external filter coupled between the external connection pad and the further connection pad.

The signal transmitter may be coupled to a second external connection pad of the integrated circuit(s) for providing the signal for transmission to an antenna external to the or each integrated circuit.

The signal receiver may be coupled to the second external connection pad of the integrated circuit(s) for receiving the received radio signal from the antenna external to the or each integrated circuit.

The signal receiver may be coupled to a third external connection pad of the integrated circuit(s) for receiving the received radio signal from an antenna external to the or each integrated circuit.

The transceiver circuit may comprise an antenna balancing circuit coupled to a fourth external connection pad of the integrated circuit(s). By that fourth pad the balancing circuit may be coupled to the first external connection pad by a transmission line external to the or each integrated circuit.

The antenna balancing circuit may have a grounding node for grounding the antenna balancing circuit. The grounding node may be coupled to a fifth external connection pad of the integrated circuit(s).

The transceiver circuit may comprise a switch for selectively coupling the fourth external connection pad to the first external connection pad.

The or each balancing circuit may comprise a network including one or more capacitors and one or more inductors.

A single integrated circuit may carry at least part of the cancellation circuit and a duplexer for coupling the transmitter and the receiver to an antenna. The transmitter and receiver may be implemented off that integrated circuit.

According to another aspect there may be provided a transceiver device comprising: a transceiver circuit as set out above; one or more antennas external to the integrated circuit(s), each coupled to one or both of the signal transmitter and the signal receiver; and a matching circuit external to the integrated circuit(s) and coupled to the first external connection pad for at least partially matching the response of the antenna.

The matching circuit may comprise a first transmission line.

The or at least one of the antenna(s) may be coupled to the integrated circuit(s) by a second transmission line. The length of the first transmission line may match that of the second transmission line.

The transmission line may couple the first external connection pad to the fourth external connection pad.

The matching circuit may comprise a balancing circuit comprising a network including one or more capacitors and one or more inductors.

According to a further aspect there is provided a transceiver circuit implemented on one or more integrated circuits, the transceiver circuit comprising: a signal transmitter for forming a radio signal for transmission; a signal receiver for performing receive processing on a received radio signal; and a cancellation circuit for at least partially cancelling components of the signal for transmission in the signal receiver, the cancellation circuit comprising a first circuit path arranged to receive an input from the signal transmitter and extending to a first external connection pad of the or one of the integrated circuits(s) and a second circuit path extending between a second external connection pad of the or one of the integrated circuit(s) and a cancellation path for providing cancellation feedback to the signal receiver, the first and second paths being connectable to each other by a component external to the integrated circuits.

At least one of the first and second paths may comprise an adjustable filter.

The signal transmitter may be coupled to a third external connection pad of the integrated circuit(s) for providing the signal for transmission to an antenna external to the or each integrated circuit.

The signal receiver may be coupled to the third external connection pad of the integrated circuit(s) for receiving the received radio signal from the antenna external to the or each integrated circuit.

The signal receiver may be coupled to a fourth external connection pad of the integrated circuit(s) for receiving the received radio signal from an antenna external to the or each integrated circuit.

The transceiver circuit may comprise an antenna balancing circuit coupled to a fifth external connection pad of the integrated circuit(s), whereby the balancing circuit can be coupled to the first and or second external connection pad(s) by a transmission line external to the or each integrated circuit.

The antenna balancing circuit may have a grounding node for grounding the antenna balancing circuit. The grounding node may be coupled to a sixth external connection pad of the integrated circuit(s).

The transceiver circuit may comprise a switch for selectively coupling the fifth external connection pad to the first external connection pad.

The or each balancing circuit may comprise a network including one or more capacitors and one or more inductors.

A single integrated circuit may carry at least part of the cancellation circuit and a duplexer for coupling the transmitter and the receiver to an antenna. The transmitter and receiver may be implemented off that integrated circuit.

There may be a component external to the integrated circuits connecting first and second paths to each other. That component may be a passive conductor. That component may be a filter, optionally an adjustable filter.

According to a further aspect there is provided a transceiver device comprising: a transceiver circuit as set out above; one or more antennas external to the integrated circuit(s), each coupled to one or both of the signal transmitter and the signal receiver; and a matching circuit external to the integrated circuit(s) and coupled to one or both of the first and second external connection pads for at least partially matching the response of the antenna.

The matching circuit may comprise a first transmission line.

The or at least one of the antenna(s) may be coupled to the integrated circuit(s) by a second transmission line and the length of the first transmission line matches that of the second transmission line.

The matching circuit may comprise a balancing circuit comprising a network including one or more capacitors and one or more inductors.

The matching circuit may be configured to mimic the response of the antenna(s) as influenced by any one or more of: the length of one or more signal lines coupling the antenna(s) to the transceiver circuit, the positioning of the antenna relative to other components of the transceiver device, a mechanical housing of the transceiver device and one or more ground planes of the transceiver device that is/are associated with the antenna.

According to a further aspect there is provided a transceiver circuit comprising: a signal transmitter for forming a radio signal for transmission; a signal receiver for performing receive processing on a received radio signal; a balancing circuit; and a cancellation circuit for at least partially cancelling components of the signal for transmission in the signal receiver, the cancellation circuit being arranged to receive an input from the signal transmitter and to provide a cancellation output to the signal receiver, the cancellation circuit being configured to form the cancellation output in dependence on both the input from the signal transmitter and a response of the balancing circuit to an intermediate signal formed by the cancellation circuit in dependence on the input from the signal transmitter; wherein: the balancing circuit comprises one or more elements that are configured so as to be switchably enabled or disabled for altering the response of the balancing circuit.

The balancing circuit and the cancellation circuit may be formed on a single integrated circuit.

The cancellation circuit may be formed on an integrated circuit having a first substrate. At least one of the said elements may be formed on a second substrate.

The first substrate and the second substrate may be of different materials.

At least one of the said elements may be a transmission line.

The transmission line may be coupled so as to carry surface waves derived from the intermediate signal.

The transceiver circuit may be implemented on a single integrated circuit.

The response received from the first external connection pad of one of the integrated circuits may be an analog signal.

The cancellation circuit may form the cancellation output by electrically combining the input from the signal transmitter and the response received from the first external connection pad of one of the integrated circuits. That combination may be performed contemporaneously with the said cancelling.

The response received from the first external connection pad of one of the integrated circuits may be derived from an output of the signal transmitter.

The response received from the first external connection pad of one of the integrated circuits may be derived from an input to the cancellation circuit. That input may be formed in dependence on the input from the signal transmitter.

Where the cancellation circuit comprises a first adjustable filter coupled between the signal transmitter and the external connection pad and a second adjustable filter coupled between a further external connection pad, the external connection pad and the further connection pad might not be interconnected on the integrated circuit. Thus the cancellation circuit may be such as to operate when enabled by an external connection between two or more nodes thereof. Alternatively the cancellation circuit may be embodied on the integrated circuit(s) in such a way that it is capable of operating without the need for an external connection between two nodes of the cancellation circuit.

The entirety of the transceiver circuit may be implemented on a single integrated circuit. The integrated circuit may have a single semiconductor die or multiple semiconductor dies. The integrated circuit may be packaged such that it has multiple pads for electrical connection to external components. The transceiver device may comprise a circuit board on which the integrated circuit is mounted. The transceiver device may comprise an external housing which contains the circuit board. The or each antenna may be comprised in the housing. The transceiver device may, for example, be a mobile or cellular telephone, or another form of end-user device or terminal device or user equipment device. The transceiver device may be a base station or base transceiver station or network equipment device.

The transceiver may comprise a transmit circuit and a receive circuit. The transmit circuit may comprise a bandpass filter having a passband that encompasses a transmit frequency band of the transceiver and a stop band that encompasses a receive frequency band of the receiver. A control circuit may control the response of the first and second filters in response to a signal that is input to the bandpass filter, or in dependence on which the input to the bandpass filter is formed. The receive circuit may comprise a bandpass filter having a passband that encompasses the receive frequency band of the transceiver and a stop band that encompasses the transmit frequency band of the receiver. An output of the cancellation circuit may feed to the output of the bandpass filter of the receive circuit, or to a signal formed in dependence on that output.

The present invention will now be described by way of example with reference to the accompanying drawings. In the drawings:

FIG. 1 shows a transceiver circuit

FIG. 2 shows a transceiver circuit with a cancellation path.

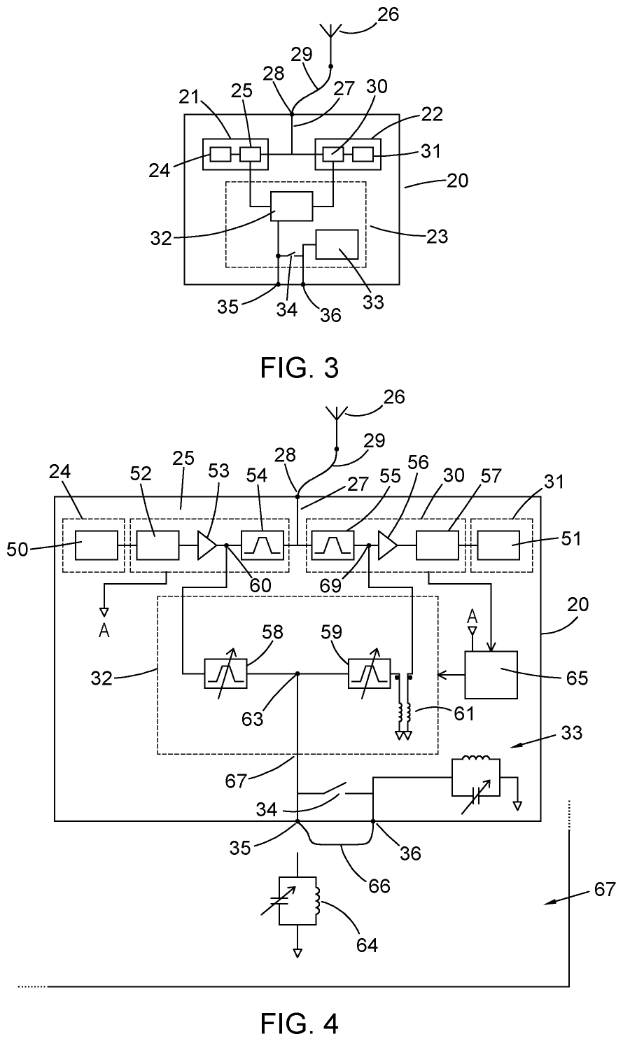

FIG. 3 is a block diagram of a transceiver formed on an integrated circuit.

FIG. 4 shows the transceiver of FIG. 3 in more detail.

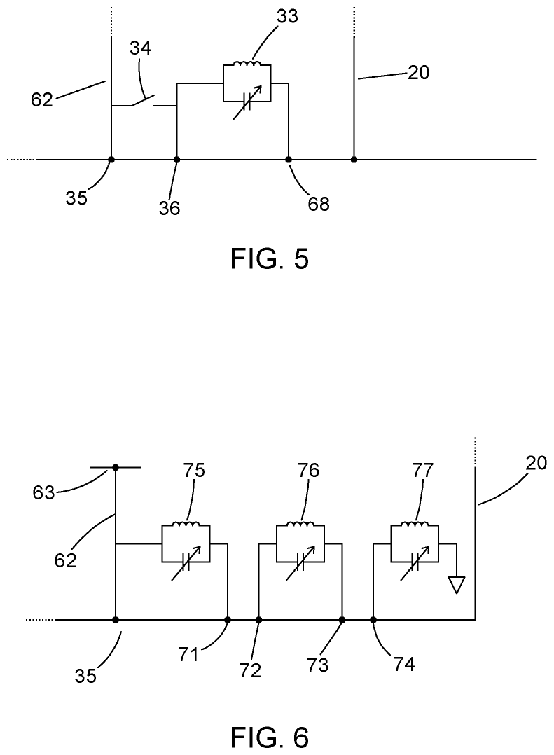

FIG. 5 shows part of the circuit of an alternative design of transceiver.

FIG. 6 shows part of the circuit of another alternative design of transceiver.

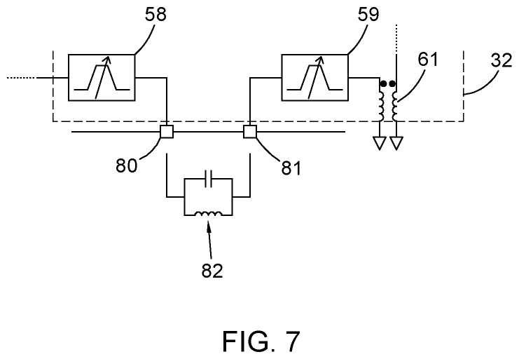

FIG. 7 shows part of a circuit for use with a series external filter.

FIG. 3 shows a radio frequency architecture for transmitting and receiving radio signals. The transceiver is formed on a single integrated circuit (IC) 20. The transceiver comprises a transmit module 21, a receive module 22 and a cancellation module 23. The transmit module forms a signal for transmission. The receive module processes a received signal. The cancellation module generates a cancellation signal in dependence on an input from the transmit module, and feeds the cancellation signal to the receive module for at least partially cancelling any component of the transmit signal that may have fed through into the receive module.

In this example the transmit module 21 comprises a digital section 24 and a radio frequency (RF) section 25. The digital section forms a digital data signal for transmission. That signal is passed to the RF section 25. The RF section converts the digital signal to a radio frequency signal and amplifies it so that it is suitable for output to antenna 26. The details of the digital signal will depend on the protocol being used and the content of the message that is to be transmitted. The form and frequency spectrum of the radio frequency spectrum will depend on the air interface protocol being used. The output of RF section 25 passes to a signal line 27. Signal line 27 is connected to an external pad 28 of the integrated circuit 20. Antenna 26 is connected to the antenna pad 28 by a transmission line 29. Variations of this circuit are possible. For example, the digital section 24 could be implemented off integrated circuit 20. Examples of functions the RF transmitter section may perform include any one or more of digital-to-analogue conversion, modulation, mixing, amplification and filtering.

In this example the receive module 22 comprises an RF receiver section 30 and a digital receiver section 31. The RF receiver section 30 is coupled to antenna 26 via transmission line 29, pad 28 and signal line 27. RF signals received by antenna 26 can therefore pass to the RF receiver section 30. The RF receiver section processes the received signals to convert them to a signal suitable for input to the digital section 31. The digital section 31 then further processes the signals to detect and analyse their data content. Variations of this circuit are possible. For example, the digital section 31 could be implemented off integrated circuit 20. Examples of functions the RF receiver section may perform include any one or more of analogue-to-digital conversion, demodulation, mixing, amplification and filtering.

The signal transmitter may be considered to be those components that form the signal for transmission, for example to generate, encode, filter, modulate or amplify that signal. Such components may operate in the analog or digital domains. Such components may operate at radio frequency or baseband. The signal receiver may be considered to be those components that process the received signal, for example to detect, decode, demodulate, filter or amplify that signal. Such components may operate in the analog or digital domains. Such components may operate at radio frequency or baseband. In one example, the signal receiver may comprise the receive signal chain from a node where it combines with the transmit signal chain to an interface where it outputs a digital representation of the received signal.

The cancellation module 23 receives an input from the transmit module 24. The input represents an analogue signal that is being fed by transmit module into the signal line 27 that links the transmit and receive modules. The cancellation module comprises circuitry for generating, in dependence on the input, a signal at the output of the cancellation module that is suitable for at least partially cancelling, at the receive module 22, a component of the transmit signal that may have passed to the receive module. To that end the cancellation module comprises a signal shaping module 32 and a balancing impedance module 33. The signal shaping module 32 processes the signal received from the transmit module 24 to generate a signal of a suitable form for providing cancellation at the receive module. Generating this signal may require the impedance of the antenna to be compensated for using a balancing impedance. The balancing impedance module 33 provides an impedance for connection to the signal shaping module so as to at least partially imitate the effect of the impedance load on signal line 27. It may substantially imitate such an effect. The balancing impedance module can be invoked in two modes. In a first mode, switch 34 is closed, coupling the balancing impedance module to the signal shaping module by a path lying entirely on the integrated circuit on which the signal shaping module and the balancing impedance module are defined. In a second mode, components off the integrated circuit couple the signal shaping module 32 to the balancing impedance module. The off-chip components are connected between external connection pads 35, 36 of the integrated circuit. Pad 35 is coupled on-chip to the signal shaping module 32. Pad 36 is coupled on-chip to the balancing impedance module 33. In the second mode the switch 34 may be open or closed. If the switch is open, module 32 is coupled to module 33 only by a path that extends off the integrated circuit. If the switch is closed, the module 32 is coupled to module 33 by both (i) a first path that lies entirely on the integrated circuit and (ii) a second path that lies in part off the integrated circuit.

A circuit of the type shown in FIG. 3 may provide a number of advantages. It is common to manufacture IC 20 for use in multiple different communication products. Those products may have different antennas and transmission lines 29 of different lengths and configurations, depending on the size, shape and internal packaging of the products. Nevertheless, it is desirable for the balancing impedance to closely balance the impedance of antenna 26 and transmission line 29. With the arrangement of FIG. 3, the product's manufacturer can connect suitable circuit elements between pads 35 and 36 so that the specific impedance characteristics of the antenna components in the product can be closely balanced. The product manufacturer is not restricted to the components that are on IC 20. The product manufacturer can provide passive or active components coupled between pads 35 and 36, or between one or both of pads 35 and 36 and an external node such as circuit ground. In that way the product manufacturer can adapt the performance of the integrated circuit to a particular product design. This facility can allow a manufacturer of IC 20 to reduce the complexity of IC 20 whilst still having the IC compatible with a substantial range of end products. It may also allow the product manufacturer to use bulky components with the balancing circuit without the IC manufacturer needing to provide those components on the IC. Some components, such as inductors, and/or transmission lines, can occupy considerable IC die area.

FIG. 4 shows in more detail one circuit for implementing the architecture of FIG. 3. In FIG. 4 like components are numbered as in FIG. 3.

Digital sections 24 and 31 comprise digital signal processors (DSPs) 50 and 51 respectively. These may be constituted by the same physical processor or by different processors.

RF and/or analogue transmitter section 25 comprises a pre-processing unit 52, an amplifier 53 and a filter 54. The pre-processing unit performs functions such as digital-to-analogue conversion of the signal from digital module 24, modulation, frequency shifting and signal conditioning. The output from pre-processing unit 52 is a radio frequency signal. Amplifier 53 is a power amplifier for amplifying that radio frequency signal. Filter 54 is a filter for filtering the output of amplifier 53. The output of the filter goes to the line 27 which is coupled to the antenna. Conveniently filter 54 is a bandpass filter arranged to attenuate frequencies outside the desired transmission band of the system. It may alternatively be a low pass filter or a high pass filter. It is preferred that filter 54 substantially attenuates frequencies in the desired receive band of the system, to reduce their presence at the input to receiver block 30. For example, it may attenuate power in the or each receive band by a factor of 10 or 100 or more relative to power in the or each transmit band. There may be multiple amplifiers 53 and/or multiple filters 54. These may be arranged in series or parallel. In some embodiments, as will be described further below, the system may have multiple transmission bands.

RF and/or analogue receiver section 30 comprises a filter 55, an amplifier 56 and an analogue processing unit 57. The filter 55 is a filter for filtering signals present at the connection 28 to the antenna 26. Those signals may comprise signals generated by the transmitter section and also signals received by the antenna 26. The aim of filter 55 is to reduce the impact of signals generated by the transmitter section on the receiver section. Conveniently filter 55 is a bandpass filter arranged to attenuate frequencies outside the desired receive band of the system. It may alternatively be a low pass filter or a high pass filter. It is preferred that filter 55 substantially attenuates frequencies in the desired transmit band of the system, to reduce their presence at the input to amplifier 56. For example, it may attenuate power in the or each transmit band by a factor of 10 or 100 or more relative to power in the or each receive band. Amplifier 56 amplifies the output of filter 55. Signal processing unit 57 performs functions such as analogue-to-digital conversion of the signal from amplifier 56, demodulation, frequency shifting and signal conditioning. The output of signal processing unit 57 passes to DSP 51 for further processing and interpretation.

It is possible that filters 54 and 55 by themselves might not completely remove elements of the transmit signal from the receive path. To that end, the cancellation circuit to be described further below can provide active cancellation of components of the transmit signal in the receive path.

The signal shaping module 32 comprises two adjustable filters 58, 59. Filter 58 receives an input from a tap 60 at the output of the transmit amplifier 53. It could alternatively be at another location in the analogue transmit path, such as at the input to that amplifier or within the signal processing unit 52. Conveniently the tap is before the filter 54. This avoids the receive band components of the input being attenuated by the filter 54. Conveniently the tap is immediately before the filter 54 and/or after amplifier 53. Filter 58 may be a bandpass filter, a low pass filter or a high pass filter. Conveniently filter 58 is a bandpass filter. Conveniently filter 58 is arranged to have a behaviour that mimics that of filter 55. Conveniently filter 58 is a bandpass filter arranged to attenuate frequencies outside the desired receive band of the system. It is preferred that filter 58 substantially attenuates frequencies in the desired transmit band of the system. For example, it may attenuate power in the or each transmit band by a factor of 10 or 100 or more relative to power in the or each transmit band. Filter 59 receives as input the output of filter 58. Filter 59 may be a bandpass filter, a low pass filter or a high pass filter. Conveniently filter 59 is a bandpass filter. Conveniently filter 59 is arranged to have a behaviour that mimics that of filter 54. Conveniently filter 59 is a bandpass filter arranged to attenuate frequencies outside the desired transmit band of the system. It is preferred that filter 59 substantially attenuates frequencies in the desired receive band of the system. For example, it may attenuate power in the or each receive band by a factor of 10 or 100 or more relative to power in the or each transmit band.

The output of filter 59 passes to a transformer 61. The purpose of transformer 61 is to invert the output signal so that it can perform cancellation with the correct phase in the input chain. Other mechanisms for inverting the filter output could be used, for example an inverting amplifier. The output of the transformer passes to a tap 69 in the receiver section 30. Conveniently the tap is between filter 55 and amplifier 56 but it could be elsewhere in the receiver chain. The transformer 61 may be included at alternative locations within the signal shaping unit. For example, instead of being connected between the output of filter 59 and the tap 69, the transformer 61 may alternatively be connected between the output of filter 58 and the input of filter 59.

A signal path 62 runs from a node 63 between filters 58 and 59 to pad 35. Pad 35 is exposed at the exterior of the integrated circuit 20. A circuit 64 formed off the integrated circuit can be connected to pad 35 to act as a balancing impedance. That circuit may, for example be formed of a combination of one or more resistors, inductors and/or capacitors. One of more of these components may optionally be tunable. That circuit can be formed so as to balance the impedance of the antenna 26. Since the antenna is off the integrated circuit, and its impedance might not be known to the manufacturer of the integrated circuit, this approach allows a manufacturer who is implementing the integrated circuit to provide a suitable balancing circuit without customising the integrated circuit. To tune the behaviour of the filters 58 and 59 a control circuit 65 can be provided. It takes input from the transmit and receive units and provides control outputs to the filter 58 and 59. The control circuit may be provided by a digital processor programmed with a strategy that has been developed to achieve affective cancellation of transmit signal components in the receive section 30. Various self-interference cancellation algorithms are known in the art and may be applied in this example.

Optionally, a balancing impedance circuit 33 may be formed on the integrated circuit. It may be formed of one or more resistors, inductors and/or capacitors. The on-chip balancing impedance circuit can be switched in by a switch 34 on the integrated circuit or by a connection 66 from pad 35 to pad 36.

As indicated above, the off-chip balancing circuit may be formed to balance the impedance of the antenna 26. In addition, the off-chip balancing circuit may be coupled to pin 35 by a transmission line. The length of that transmission line may be selected to match the length of transmission line 29 which connects the antenna to pin 28 of the integrated circuit. Transmission line 29 will introduce a delay that is dependent on its length. If the balancing impedance is not coupled in a similar way, the cancellation effect of the circuit 23 can be impaired due to frequency-dependent phase shifts. By providing the ability for a manufacturer to implement a matched transmission line off-chip, the present circuit allows the manufacturer to achieve good matching to an off-chip antenna the connection details of which are not known to the manufacturer of the integrated circuit. In an alternative arrangement, a transmission line of suitable length may be coupled between pads 35 and 36, coupling the on-chip balancing impedance 33 into circuit with a delay matched to the antenna. This is convenient, for example, if the antenna is of a standard impedance but the length of the transmission line 29 to the antenna is specific to a particular implementation. Other circuits may be connected between pads 35 and 36. For example, a filter may be connected here to provide a phase shift and/or delay. A matching network may be connected here to transform the impedance of the on-chip balancing circuit at pad 36 circuit into another impedance for connection at pad 35. This may transform the impedance of the on-chip balancing impedance 35 in a manner which improves the correspondence between the antenna impedance and balancing impedance. This may increase the level of self-interference cancellation.

Other aspects of the antenna connection or of packaging in a particular embodiment or end product may be mimicked by the balancing circuit. This may help to improve the level of self-interference cancellation at the receiver. Those aspects may include the positioning of the antenna relative to other components of the product, characteristics of a mechanical housing of the product and the nature and/or size of one or more ground planes that may be associated with the antenna.

Optionally, the balancing circuit may be adjustable. This may enable the balancing circuit to compensate for dynamic changes in the local environment which may alter the effective impedance and/or reflection coefficient of the antenna 26. This may be, for example, due the impact of a user's hand, or other objects, adjacent to the antenna. Adjustment of the balancing circuit may be achieved using tunable or adjustable components within the circuit. A bank of capacitors and switches may be included to form one or more adjustable capacitances within the balancing network. Individual capacitors or groups of capacitors may be coupled to the switches so as to be selectively switchable into or out of circuit, thereby altering the overall capacitance of the respective adjustable capacitance. One or more components within the balancing network, for example such an adjustable capacitance, may be controlled by the controller 65. The controller 65 may be configured to adjust the balancing network to improve the level of self-interference cancellation. Optionally, one or more connections may be included on the exterior of the integrated circuit to enable connection of the controller 65 to adjustable components outside of the integrated circuit. This may enable the impedance of an off-chip balancing impedance to be adjusted. This may increase the level of self-interference cancellation.

In the examples described above, a single antenna is connected to the antenna port 28, and the antenna port is electrically coupled to both the transmit and receive circuitry. Alternatively, there may be multiple antennas connected to a single antenna port. Optionally, those antennas may provide spatial diversity and/or may be adapted for transmitting and/or receiving different frequency bands. In another alternative arrangement the integrated circuit may have a first antenna port coupled to the transmit circuitry and a second antenna port coupled to the receive circuitry. Those ports might not be directly electrically connected together. A first antenna may be connected to the first antenna port and a second antenna may be connected to the second antenna port. The cancellation circuit may then cancel signal that may leak wirelessly from one antenna to the other. Thus there may be separate antennas for transmit and receive. The output of filter 54 may pass to the transmit antenna. The input of filter 55 may come from the receive antenna. There may be no wired connection from the transmit antenna to the receive antenna. Nevertheless, the receive antenna may pick up signals radiated by the transmit antenna, so again there may be a need for self-interference cancellation. Circuit 32 and its related components including pad 35 and optionally pad 36 may be used in this situation too.

Circuit 64 may be formed on a circuit board 67 on which IC 20 is mounted.

In the examples given above, the circuit for forming the cancellation signal comprises two filters (11, 12) and the balancing impedance 14. The filters may be on a single integrated circuit. The balancing impedance may at least partially be off the integrated circuit. Other designs of circuit can be used for forming the cancellation circuit. For example, the filters 11, 12 could be replaced by a single filter, or by more than two filters, or by any circuit designed to have an adjustable frequency response, for example, a network of one or more resistors, capacitors, and/or inductors, where one or more of the components is a tunable or adjustable component or is selectively switchable into or out of circuit. Where there are multiple filters they could be arranged in series or parallel. One or more filters could be replaced by an active circuit for generating a cancellation signal. Thus, in one embodiment there may be no filters in the circuit for generating the cancellation signal. For example, the circuit for generating the cancellation signal may comprise an amplifier arranged to receive a signal from the transmitter and amplify that signal to form the cancellation signal to be output to the receiver. The amplifier may be selected so that its response results in a suitable signal for at least partially cancelling components of the transmit signal that may leak to the receiver. In each case, the response or behaviour of the circuit for forming the cancellation signal, and hence the cancellation signal that it generates in response to a given signal sensed at the transmitter, can be adjusted by one or more external components. The majority of the cancellation circuit can be formed on a circuit carrier such as a circuit board or an integrated circuit. That part of the cancellation circuit may expose at least one connection off that circuit carrier to which an external component can be connected. The said part of the cancellation circuit may be configured so that its response can depend on a component that is external to a circuit carrier that bears the said part of the circuit. Many types of cancellation circuit are known and may be implemented in this manner.

Thus, the system may provide a transmitter circuit and a receiver circuit. They may be arranged in such a way that it is possible for the receiver circuit to receive interference from the transmitter circuit. That may be referred to as self-interference. There may be a cancellation circuit, e.g. arranged as described above, that takes an input from the transmitter circuit and generates an output in dependence on that input. The cancellation circuit may be configured to generate the output such that it is capable of at least partially cancelling self-interference in the receiver. The output may be supplied to the receiver for cancelling a component in a signal at the receiver. The response of the cancellation circuit for generating such a signal may be dependent on an external component connected to the cancellation circuit. Conveniently, the response of the cancellation circuit may be dependent on the reactive properties of that external component. Alternatively, the response of the cancellation circuit may be dependent on another property of the external component. For example, the cancellation circuit may have multiple operating modes and it may respond to a property of the external component to select which operating mode it is to operate in. That property may, for example, be a digital or analogue signal supplied by the external component.

A part of the self-interference canceller may be formed on a single integrated circuit. The response of that part may be sensitive to an off-chip component that is connected to the self-interference canceller.

FIG. 5 shows another arrangement. Only part of IC 20 is shown in FIG. 5. The balancing circuit 33 is provided on the integrated circuit 20. A pad 68 is exposed at the exterior of the integrated circuit and is coupled to a grounding point of the balancing circuit. An off-chip circuit ground can be connected to pad 68. This can allow for improved grounding of the balancing circuit, for example to better match the grounding of the antenna 26. This approach may be used with any of the on-chip balancing circuit implementations described herein.

FIG. 6 shows another arrangement. Only part of IC 20 is shown in FIG. 5. Multiple LC networks 75, 76, 77 are provided on the integrated circuit. Each of the LC networks may be unconnected on the integrated circuit to the others. One or more of the LC networks (e.g. network 75) may be connected on the chip to node 63. Another point on that/those network(s) may be connected to a pad 71 exposed at the exterior of the chip. That/those networks may be unconnected on the integrated circuit to a ground point. One or more of the LC networks (e.g. network 76) may be unconnected on the integrated circuit to both node 63 and any ground point. Two points on that/those network(s) may be connected to respective pads 72, 73 exposed at the exterior of the chip. One or more of the LC networks (e.g. network 77) may be unconnected on the integrated circuit to node 63 but connected on the integrated circuit to a ground. A point on that/those network(s) may be connected to a pad 74 exposed at the exterior of the chip. By applying connections exterior to the chip between selected ones of pads 35, 71, 72, 73 and 74 these networks may be connected together to configure a balancing network of a desired response through off-chip connections. These connections may be made using transmissions line and/or traces on a circuit board or circuit carrier to which the integrated circuit is mounted. Alternatively or additionally, these connections may be made via other components, for example, capacitors and/or inductors connected between the two or more of the pads 35, 72, 72, 73, and/or 74. This can allow a manufacturer to provide a suitable balancing network for a particular implementation. The manufacturer may form a balancing network by optionally connecting components internal and/or external to the integrated circuit together to form a network. One or more connections between those pads may be by a transmission line of a length selected to match transmission line 29. One of more of the components within the networks 75, 76, 77 may be tunable or adjustable. One or more external components within the balancing network may be adjustable. Networks 75, 76, and/or 77 may optionally be adjusted by the controller 65.

In embodiments described above, the transmitter circuit, receiver circuit and the cancellation circuit may be implemented on a single, common integrated circuit. Other configurations are possible. For example, the cancellation circuit could be implemented on an integrated circuit that does not bear the transmitter and receiver circuits. That integrated circuit could optionally comprise a duplexer having an input for receiving a transmit signal input from the transmit circuit, an output for providing a receive signal output to the receive circuit and a port for connection to the antenna. The input, output and port could be connections, e.g. contact pads, at the exterior of that integrated circuit, for connection to external components. The integrated circuit could have a further connection, e.g. a contact pad, at the exterior of the integrated circuit for connection to an external component on which the response of the cancellation circuit is dependent. In one example an integrated circuit may comprise the self-interference cancellation circuit 32 and a duplexer for coupling a transmit circuit and a receive circuit to an antenna and other parts of a transmitter and a receiver may be omitted from that integrated circuit. They may be implemented elsewhere. For example, that integrated circuit may include no transmit amplifier and/or no receive amplifier and/or no transmit filter and/or no receive filter. Any one or more of those components may be implemented on a second integrated circuit.

The self-interference cancellation path passes from the transmit section 21 to the receive section 22 through circuit block 32. As indicated above, a functional external circuit may be connected to node 35 to alter the response of the self-interference cancellation circuit. Active circuitry may be provided to alter the response of that external circuit. The active circuit may be responsive to, for example, any one or more of the following factors to alter that response: an input representing a configuration of the antenna and/or a connection to it as selected from a predetermined set of configurations; an indication of a measurement of a physical characteristic of the antenna and/or a connection to it, for example its impedance or frequency response; a degree of self-interference cancellation achieved at the receiver by the self-interference cancellation circuit. That active circuitry may be on or off an integrated circuit on which the self-interference cancellation circuit is defined. It may, for example, comprise a processor configured to execute code stored in non-transient form and having an output that can alter the behaviour of the functional external circuit, e.g. by switching components of it into or out of circuit. Controller 65 may provide some or all of this functionality.

As indicated at 33, some or all of the balancing circuit may be implemented on an integrated circuit common to the self-interference cancellation circuit. That part of the balancing circuit may comprise multiple reactive elements that can be switched in or out of circuit by switches provided on the integrated circuit or on one or more other circuit carriers such as integrated circuits or circuit boards. In that way the behaviour of the balancing circuit may be altered. One aspect of an antenna implementation that it may be desired to compensate for with such a circuit is the length of any connection from an antenna port (e.g. 28) to an antenna. One way in which that may be compensated for is by that part of the balancing circuit comprising multiple transmission line segments that can be switched into or out of circuit so as to together form a transmission line of a selected length. One or more of those transmission lines may be formed in a material in which signals travel slower than on a conductive line or slower than another of those transmission lines. For example, one or more of those transmission lines may be formed on a ceramic substrate. It may carry the signals as a surface wave. This approach may allow transmission lines for compensating for antenna connections of longer length to be more easily packaged on a small circuit carrier. In this arrangement, external connection 35 could optionally be omitted.

In another embodiment, external components may be connected in series in a cancellation path. In such an embodiment, the self-interference cancellation circuit may not be formed to provide a continuous cancellation path within an integrated circuit. In this sense the self-interference cancellation circuit may be incomplete within the integrated circuit or only partially located within the integrated circuit. For example, there might not be a connection on the integrated circuit between the output of filter 58 and the input of filter 59. The output of filter 58 and the input of filter 59 may instead by connected to separate external connections. This may allow a series network including one or more external components and/or transmission lines to be connected in between the output of filter 58 and the input of filter 59. The series network may contain one or more of the following: inductors, capacitors, resistors, active components (e.g. amplifiers), filters, transmission lines, hybrid circuits, and/or transformers. The series network may contain components in series and/or parallel. The series network may contain one or more connections to electrical ground. The series network may be connected to complete the self-interference canceller circuit. This may, for example, enable the cancellation network topology to be selected or the behaviour or response of the cancellation network to be modified after the integrated circuit has been manufactured. This may be beneficial in allowing the cancellation circuit to be adapted by a manufacturer to a particular application. For example, where separate transmitting and receiving antennas are used, the series network may be designed using knowledge of the antenna structures which may not be available at the time the integrated circuit is designed. This may enable the cancellation circuit to be adapted to improve the cancellation of self-interference which may be coupled between a transmitting and a receiving antenna. One or more components within the integrated circuit may be optionally included in the series network using optional connections external to the integrated circuit or using switches within the integrated circuit. The construction and/or connection and/or configuration of the series network may be performed in a similar manner to that which is described above with reference to external circuits being connected via external connection 35, but with external components of the series network being connected in series to complete a self-interference cancellation circuit, instead of a balancing network being connected in parallel to adjust the response of a self-interference cancellation circuit.

FIG. 7 shows a part of the circuit of FIG. 4 adapted to the arrangement described above. The output of filter 58 is coupled to a pad 80 on the exterior of the integrated circuit. The input of filter 59 is coupled to a pad 81 on the exterior of the integrated circuit. With nothing connected between pads 80 and 81 filter 58 and 59 are not interconnected. A filter 82 can be connected between pads 80 and 81 to complete the circuit. Filter 82 may take any form. Pads 80 and 81 may be connected directly together with no external filter. In that case the entirety of the filtering circuitry may be constituted on the integrated circuit.

The pads 35 etc. may take any suitable form. They may, for example, be conductive lands for receiving solder, conductive pins or solder balls.

Some radio transceivers implement carrier aggregation. In carrier aggregation multiple transmit signals with different carrier frequencies are passed to a common antenna, and multiple receive signals with different carrier frequencies are received with a common antenna. The circuits described above may be used in carrier aggregation transceivers. The filters 58, 59 may be compound filters for matching the effect of multiple corresponding filters in the transmit and receive sections.

The or each balancing circuit or LC network may be formed of any suitable arrangement of reactive and/or resistive components, for example inductors, capacitors and resistors. The components may be selected and connected together to provide the circuit with a suitable response. The circuit may be a filter circuit. The circuit may have a frequency-dependent response. The circuit may provide a reactance.

A transceiver of the type described herein may be suitable for transmitting and receiving signals of protocols such as 5G, 4G, 3G, WiFi/IEEE 802.11 or Bluetooth.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

The phrase “configured to” or “arranged to” followed by a term defining a condition or function is used herein to indicate that the object of the phrase is in a state in which it has that condition, or is able to perform that function, without that object being modified or further configured.

1-38. (canceled)

39. A transceiver circuit implemented on one or more integrated circuits, the transceiver circuit comprising:
a signal transmitter for forming a radio signal for transmission;
a signal receiver for performing receive processing on a received radio signal; and
a cancellation circuit for at least partially cancelling components of the signal for transmission in the signal receiver, the cancellation circuit being arranged to receive an input from the signal transmitter and to provide a cancellation output to the signal receiver, the cancellation circuit being configured to form the cancellation output in dependence on both the input from the signal transmitter and a response received from a first external connection pad of the or one of the integrated circuit(s).

40. A transceiver circuit as claimed in claim 39, wherein the said response is a reactive response to a signal formed by the cancellation circuit in dependence on the input from the signal transmitter.

41. A transceiver circuit as claimed in claim 39, wherein the cancellation circuit comprises a first adjustable filter coupled between the signal transmitter and the external connection pad and a second adjustable filter coupled between the external connection pad and the signal receiver.

42. A transceiver circuit as claimed in claim 39, wherein the signal transmitter is coupled to a second external connection pad of the integrated circuit(s) for providing the signal for transmission to an antenna external to the or each integrated circuit.

43. A transceiver circuit as claimed in claim 39, wherein the signal receiver is coupled to a third external connection pad of the integrated circuit(s) for receiving the received radio signal from an antenna external to the or each integrated circuit.

44. A transceiver circuit as claimed in claim 39, wherein the transceiver circuit comprises an antenna balancing circuit coupled to a fourth external connection pad of the integrated circuit(s), whereby the balancing circuit can be coupled to the first external connection pad by a transmission line external to the or each integrated circuit.

45. A transceiver circuit as claimed in claim 44, wherein the antenna balancing circuit has a grounding node for grounding the antenna balancing circuit and the grounding node is coupled to a fifth external connection pad of the integrated circuit(s).

46. A transceiver circuit as claimed in claim 44, wherein the transceiver circuit comprises a switch for selectively coupling the fourth external connection pad to the first external connection pad.

47. A transceiver circuit as claimed in claim 44, wherein the or each balancing circuit comprises a network including one or more capacitors and one or more inductors.

48. A transceiver device comprising:
a transceiver circuit as set forth in claim 39;
one or more antennas external to the integrated circuit(s), each coupled to one or both of the signal transmitter and the signal receiver; and
a matching circuit external to the integrated circuit(s) and coupled to the first external connection pad for at least partially matching the response of the antenna.

49. A transceiver device as claimed in claim 48, wherein the matching circuit comprises a first transmission line.

50. A transceiver device as claimed in claim 49, wherein the transceiver circuit comprises a switch for selectively coupling a second external connection pad to the first external connection pad and the transmission line couples the first external connection pad to the second external connection pad.

51. A transceiver device as claimed in claim 39, wherein the matching circuit comprises a balancing circuit comprising a network including one or more capacitors and one or more inductors.

52. A transceiver circuit implemented on one or more integrated circuits, the transceiver circuit comprising:
a signal transmitter for forming a radio signal for transmission;
a signal receiver for performing receive processing on a received radio signal; and
a cancellation circuit for at least partially cancelling components of the signal for transmission in the signal receiver, the cancellation circuit comprising a first circuit path arranged to receive an input from the signal transmitter and extending to a first external connection pad of the or one of the integrated circuits(s) and a second circuit path extending between a second external connection pad of the or one of the integrated circuit(s) and a cancellation path for providing cancellation feedback to the signal receiver, the first and second paths being connectable to each other by a component external to the integrated circuits.

53. A transceiver circuit as claimed in claim 52, wherein the signal transmitter is coupled to a third external connection pad of the integrated circuit(s) for providing the signal for transmission to an antenna external to the or each integrated circuit.

54. A transceiver device comprising:
a transceiver circuit as claimed in claim 52;
one or more antennas external to the integrated circuit(s), each coupled to one or both of the signal transmitter and the signal receiver; and
a matching circuit external to the integrated circuit(s) and coupled to one or both of the first and second external connection pads for at least partially matching the response of the antenna.

55. A transceiver circuit comprising:
a signal transmitter for forming a radio signal for transmission;
a signal receiver for performing receive processing on a received radio signal;
a balancing circuit; and
a cancellation circuit for at least partially cancelling components of the signal for transmission in the signal receiver, the cancellation circuit being arranged to receive an input from the signal transmitter and to provide a cancellation output to the signal receiver, the cancellation circuit being configured to form the cancellation output in dependence on both the input from the signal transmitter and a response of the balancing circuit to an intermediate signal formed by the cancellation circuit in dependence on the input from the signal transmitter;
wherein:
the balancing circuit comprises one or more elements that are configured so as to be switchably enabled or disabled for altering the response of the balancing circuit.

56. A transceiver circuit as claimed in claim 55, wherein the balancing circuit and the cancellation circuit are formed on a single integrated circuit.

57. A transceiver as claimed in claim 56, wherein the cancellation circuit is formed on an integrated circuit having a first substrate and at least one of the said elements is formed on a second substrate.

58. A transceiver as claimed in claim 55, wherein at least one of the said elements is a transmission line.
